(19) United States
(12) Patent Application Publication
(10) Pub. No.: US 2026/0182337 A1
(43) Pub. Date: Jun. 25, 2026

(54) CU PAD ON AL PAD FOR HYBRID BONDING LINK CONTACT RESISTANCE REDUCTION

(71) Applicant: QUALCOMM Incorporated, San Diego, CA (US)

(72) Inventors: Abhishek JAIN, San Diego, CA (US); Junjing BAO, San Diego, CA (US); Hyun LEE, San Diego, CA (US); Jihong CHOI, San Diego, CA (US)

(21) Appl. No.: 19/290,224

(22) Filed: Aug. 4, 2025

Related U.S. Application Data
(60) Provisional application No. 63/738,259, filed on Dec. 23, 2024.

(51) Int. Cl. H01L 23/522; H01L 23/00; H01L 23/532; H01L 25/18; H10B 80/00; H10D 80/30

(52) U.S. Cl. CPC H10W 20/42; H10B 80/00; H10D 80/30; H10W 20/425; H10W 90/00; H10W 72/952; H10W 72/963; H10W 72/967; H10W 80/312; H10W 80/327; H10W 90/26; H10W 90/792

(57) ABSTRACT

A three-dimensional (3D) memory structure is described. The 3D memory structure includes a first memory die having first multilayer contact pads including a first outer pad composed of a first conductive material. The 3D memory structure also includes a base logic die including second multilayer contact pads having a second outer pad composed of the first conductive material. The 3D memory structure further includes hybrid bonding links coupled between the second outer pad of the second multilayer contact pads of the base logic die and the first outer pad of the first multilayer contact pads of the first memory die. The hybrid bonding links are composed of the first conductive material.

### CROSS-REFERENCE TO RELATED APPLICATION

The present application claims the benefit of U.S. Provisional Ser. No. 63/738,259, filed Dec. 23, 2024, and titled “CU PAD ON AL PAD FOR HYBRID BONDING LINK CONTACT RESISTANCE REDUCTION,” the disclosure of which is expressly incorporated by reference herein in its entirety.

### BACKGROUND

### Field

Aspects of the present disclosure relate to integrated circuits (ICs) and, more particularly, to a copper (Cu) pad on an aluminum (Al) pad using hybrid bonding to provide link contact resistance reduction.

### BACKGROUND

Memory is a vital component for computing devices, wireless communications devices, and other like computing devices. For example, a cell phone may integrate memory as part of an application processor, such as a system-on-chip (SoC) including a central processing unit (CPU), neural processing unit (NPU), and a graphics processing unit (GPU). Successful operation of some wireless applications depends on the availability of high-capacity and low-latency memory solutions for scalability of processor workload. A semiconductor memory device solution for providing a high-capacity, low-latency, and high-bandwidth memory is an existing goal for system designers.

Semiconductor memory devices include, for example, a dynamic random-access memory (DRAM). A DRAM memory cell includes one transistor and one capacitor, thereby providing a high degree of integration. In practice, memory intensive applications (e.g., artificial intelligence (AI)) consume extensive amounts of DRAM. A high-bandwidth, high-capacity DRAM memory stack is important for enabling AI. High-bandwidth DRAM stacking involves a separate base logic die stack. Unfortunately, testing and repairing of a DRAM stack requires an aluminum pad that creates incompatible conductive material interfaces and contributes to increased contact resistance between DRAM and base logic die stack.

### SUMMARY

A three-dimensional (3D) memory structure is described. The 3D memory structure includes a first memory die having first multilayer contact pads including a first outer pad composed of a first conductive material. The 3D memory structure also includes a base logic die including second multilayer contact pads having a second outer pad composed of the first conductive material. The 3D memory structure further includes hybrid bonding links coupled between the second outer pad of the second multilayer contact pads of the base logic die and the first outer pad of the first multilayer contact pads of the first memory die. The hybrid bonding links are composed of the first conductive material.

A method for forming a three-dimensional (3D) memory structure is described. The method includes forming a first memory die including first multilayer contact pads having a first outer pad composed of a first conductive material. The method also includes forming a base logic die including second multilayer contact pads having a second outer pad composed of the first conductive material. The method further includes forming hybrid bonding links coupled between the second outer pad of the second multilayer contact pads of the base logic die and the first outer pad of the first multilayer contact pads of the first memory die. The hybrid bonding links are composed of the first conductive material.

This has outlined, broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for conducting the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates an example implementation of a host system-on-chip (SoC), including a three-dimensional (3D) memory structure having hybrid bonding links for contact resistance reduction, in accordance with certain aspects of the present disclosure.

FIG. 2 shows a cross-sectional view of a stacked integrated circuit (IC) package of a three-dimensional (3D) memory structure having a hybrid bonding link between memory parts of the host system-on-chip (SoC) of FIG. 1.

FIG. 3 shows a cross-sectional view illustrating the stacked integrated circuit (IC) package of FIG. 2, incorporated into a wireless device, according to one aspect of the present disclosure.

FIGS. 4A-4C are block diagrams illustrating three-dimensional (3D) memory stacks having hybrid bonding links for contact resistance reduction, according to various aspects of the present disclosure.

FIGS. 5A-5K are cross-sectional diagrams illustrating a process for fabricating the three-dimensional (3D) memory structure of FIG. 4A, having hybrid bonding links for contact resistance reduction, according to various aspects of the present disclosure.

FIG. 6 is a process flow diagram illustrating a method for fabricating a three-dimensional (3D) memory structure having hybrid bonding links for contact resistance reduction, according to various aspects of the present disclosure.

FIG. 7 is a block diagram showing an exemplary wireless communications system, in which an aspect of the present disclosure may be advantageously employed.

FIG. 8 is a block diagram illustrating a design workstation used for circuit, layout, and logic design of a semiconductor component such as the disclosed three-dimensional (3D) stacked chip disclosed herein.

### DETAILED DESCRIPTION

The detailed description set forth below, in connection with the appended drawings, is intended as a description of various configurations and is not intended to represent the only configurations in which the concepts described may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form to avoid obscuring such concepts.

As described, the use of the term “and/or” is intended to represent an “inclusive OR,” and the use of the term “or” is intended to represent an “exclusive OR.” As described, the term “exemplary” used throughout this description means “serving as an example, instance, or illustration,” and should not necessarily be construed as preferred or advantageous over other exemplary configurations. As described, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described, the term “proximate” used throughout this description means “adjacent, very near, next to, or close to.” As described, the term “on” used throughout this description means “directly on” in some configurations, and “indirectly on” in other configurations.

Memory is a vital component for wireless communications devices. For example, a cell phone may integrate memory as part of an application processor, such as a system-on-chip (SoC) including a central processing unit (CPU), a graphics processing unit (GPU), and a neural processing unit (NPU). Successful operation of some wireless applications depends on the availability of a high-capacity and low-latency memory solution for scalability of processor workload. A semiconductor memory device solution for providing a high-capacity, low-latency, and high-bandwidth memory is an existing goal for system designers.

Semiconductor memory devices include, for example, dynamic random-access memory (DRAM). A DRAM memory cell includes one transistor and one capacitor, thereby providing a high degree of integration. In practice, memory intensive applications (e.g., artificial intelligence (AI)) require extensive amounts of DRAM. A high-bandwidth, high-capacity DRAM memory stack is an important solution for enabling AI. High-bandwidth DRAM stacking involves a DRAM die stacked on a separate base logic die. Unfortunately, testing and repairing of a DRAM stack requires an aluminum pad that creates incompatible conductive material interfaces and contributes to increased contact resistance between DRAM and base logic die stack.

For example, hybrid bonding between two different DRAM parts (e.g., wafer or dies) involves a hybrid bonding link. Hybrid bonding links, however, are designed to land on a copper (Cu) pad. By contrast, DRAM parts are designed with aluminum (Al) pads for performing DRAM testing. Unfortunately, an increased contact resistance exhibited by a copper pad/aluminum pad interface makes hybrid bonding of DRAM parts extremely challenging to do. In practice, the copper pad/aluminum pad interface exhibits a ten-fold (10×) higher resistance. Additionally, an aluminum interface is susceptible to oxidation, which can further degrade the copper pad/aluminum pad interface quality, such as increased contact resistance at the interface. Therefore, a solution for implementing a DRAM stack using bond layer having a reduced contact resistance, is desired.

Various aspects of the present disclosure are directed to a three-dimensional (3D) memory structure having hybrid bonding links for contact resistance reduction. The process flow for fabrication of a 3D memory structure includes hybrid bonding of a DRAM die, and a base logic die using a fabrication process technology. It will be understood that the term “layer” includes film and is not construed as indicating a vertical or horizontal thickness unless otherwise stated. As described, the term “substrate” may refer to a substrate of a diced wafer or may refer to a substrate of a wafer that is not diced. As further described, the term “laminate” may refer to a multilayer sheet to enable packaging of an IC device. As described, the term “chiplet” may refer to an integrated circuit block, a functional circuit block, or other like circuit block specifically designed to work with other similar chiplets to form a larger, more complex chiplet architecture. The terms “substrate,” “wafer,” and “laminate” may be used interchangeably.

Various aspects of the present disclosure are directed to a three-dimensional (3D) memory structure having hybrid bonding links for contact resistance reduction. Various aspects of the present disclosure utilize hybrid bonding links for enabling DRAM testing and repair using aluminum (Al) test pads, while supporting a lower contact resistance. In some implementations, a multilayer contact pad utilizes a thin film of titanium nitride (TiN) as a buffer layer to prevent oxidation of the Al test pads, which forms an inner pad of the of the multilayer contact pad. In this implementation, contact resistance is lowered by performing copper (Cu) pad deposition as an outer pad on active Al/TiN pads post-test and/or repair, which completes formation of the multilayer contact pads.

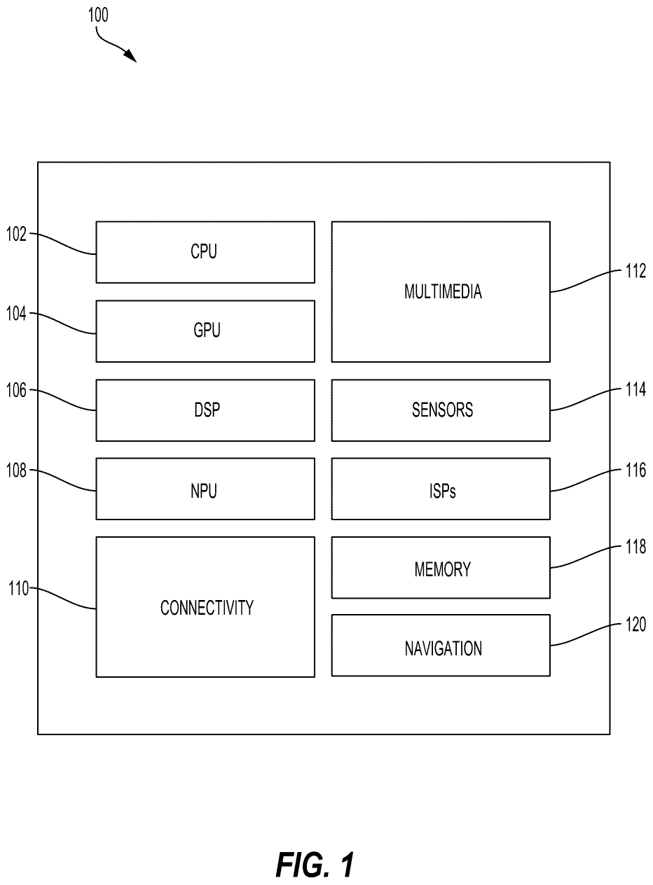

FIG. 1 illustrates an example implementation of a host system-on-chip (SoC) 100, which includes a three-dimensional (3D) memory structure having hybrid bonding links for contact resistance reduction, in accordance with certain aspects of the present disclosure. The host SoC 100 includes processing blocks tailored to specific functions, such as a connectivity block 110. The connectivity block 110 may include sixth generation (6G) connectivity, fifth generation (5G) new radio (NR) connectivity, fourth generation long term evolution (4G LTE) connectivity, Wi-Fi connectivity, USB connectivity, Bluetooth^{®}connectivity, Secure Digital (SD) connectivity, and the like.

In this configuration, the host SoC 100 includes various processing units that support multi-threaded operation. For the configuration shown in FIG. 1, the host SoC 100 includes a multi-core central processing unit (CPU) 102, a graphics processor unit (GPU) 104, a digital signal processor (DSP) 106, and a neural processor unit (NPU) 108. The host SoC 100 may also include a sensor processor 114, image signal processors (ISPs) 116, a navigation module 120, which may include a global positioning system (GPS), and a memory 118. The multi-core CPU 102, the GPU 104, the DSP 106, the NPU 108, and the multimedia engine 112 support various functions such as video, audio, graphics, gaming, artificial networks, and the like. Each processor core of the multi-core CPU 102 may be a reduced instruction set computing (RISC) machine, RISC-V, an advanced RISC machine (ARM), a microprocessor, or any reduced instruction set computing (RISC) architecture. The NPU 108 may be based on an ARM instruction set.

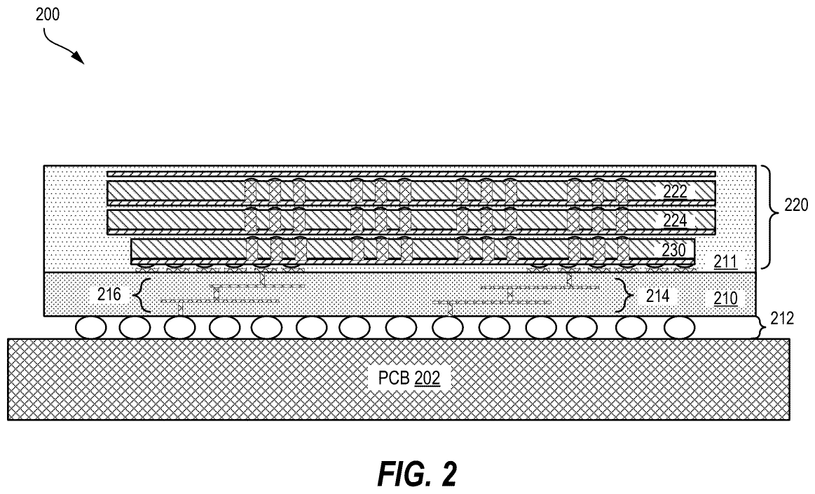

FIG. 2 shows a cross-sectional view of a stacked integrated circuit (IC) package 200 of a three-dimensional (3D) memory structure having hybrid bonding links for contact resistance reduction of the host system-on-chip (SoC) 100 of FIG. 1. Representatively, the stacked IC package 200 includes a printed circuit board (PCB) 202 connected to a package substrate 210 with interconnects 212. In this configuration, the package substrate 210 includes conductive layers 214 and 216. Above the package substrate 210 is a 3D chip stack 220, including stacked dies 222, 224, and 230, encapsulated by mold compound 211. In one aspect of the present disclosure, the die 230 is the three-dimensional (3D) memory structure having hybrid bonding links for contact resistance reduction of the host SoC 100 of FIG. 1.

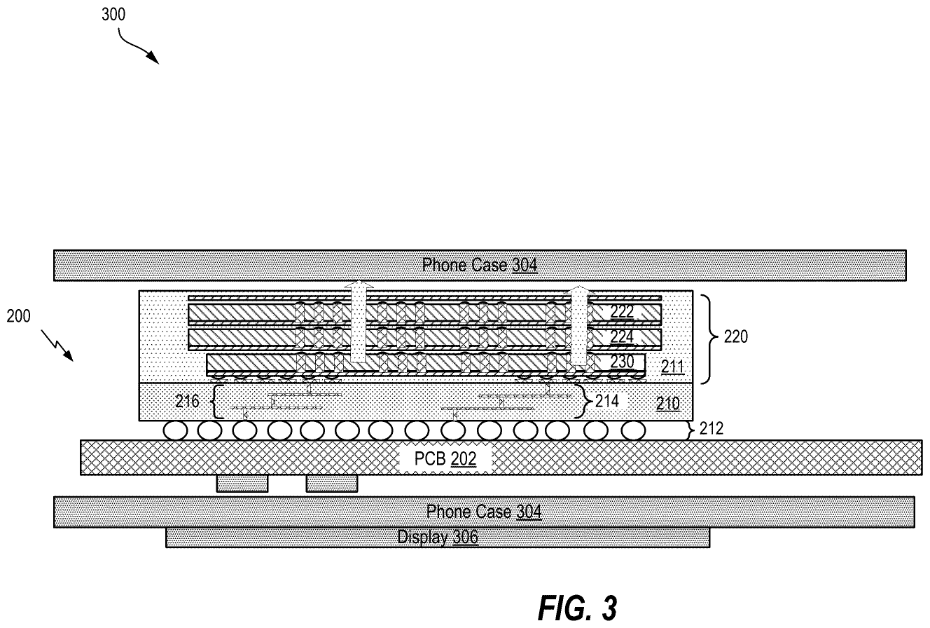

FIG. 3 shows a cross-sectional view illustrating the stacked integrated circuit (IC) package 200 of FIG. 2, incorporated into a wireless device 300, according to one aspect of the present disclosure. As described, the wireless device 300 may include, but is not limited to, a smartphone, tablet, handheld device, or other limited form factor device configured for 5G NR/ 6G communications. Representatively, the stacked IC package 200 is within a phone case 304, including a display 306.

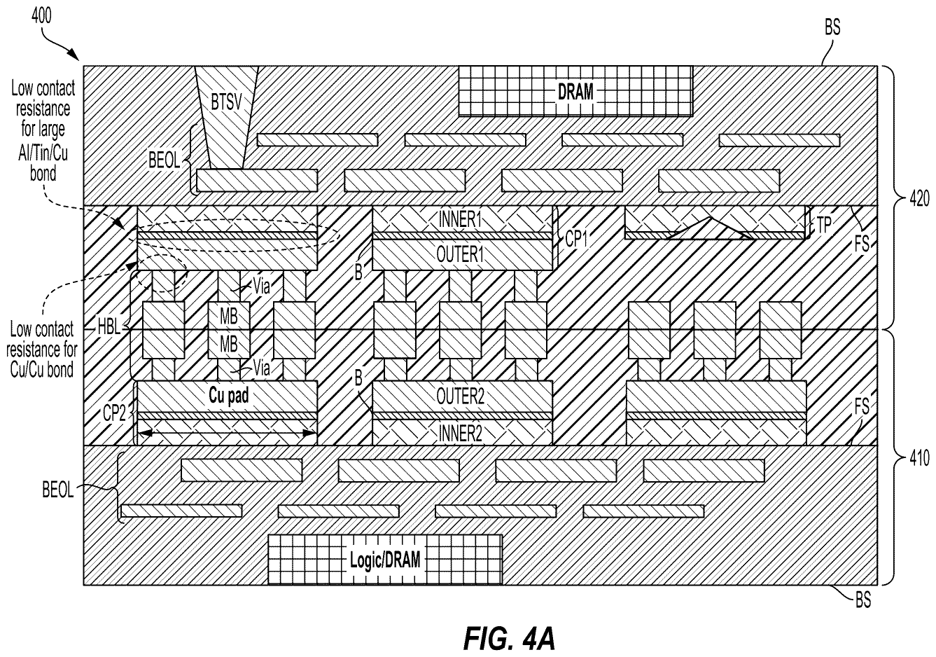

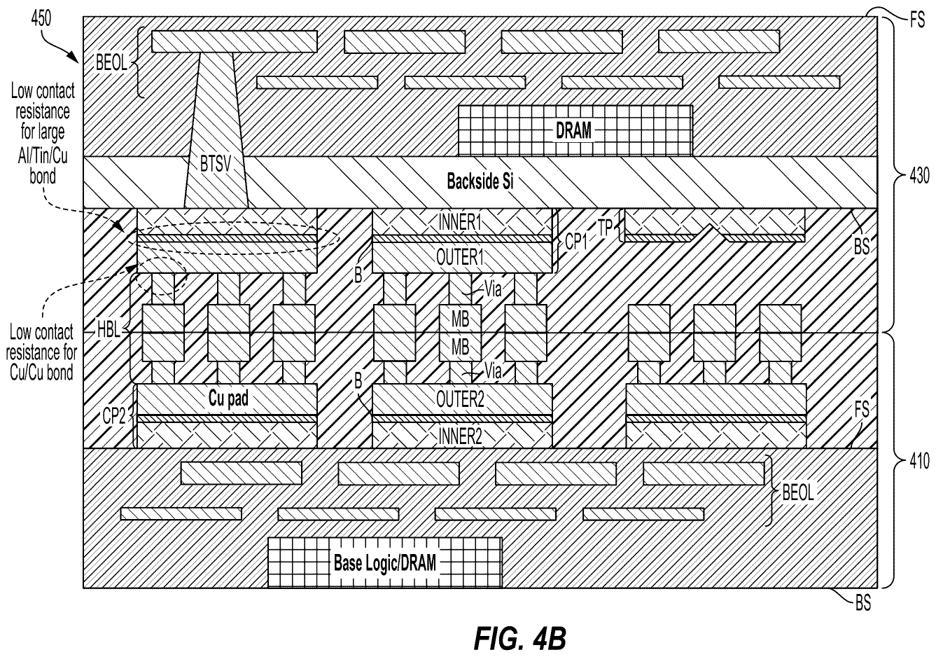

FIGS. 4A-4C are block diagrams illustrating 3D memory stacks having hybrid bonding links for contact resistance reduction, according to various aspects of the present disclosure. As shown in FIG. 4A, a 3D memory structure 400 is implemented using a hybrid bonding links to provide face-to-face (F2F) hybrid bonding of a first memory die 420 and a base logic die 410 of, for example, a high-bandwidth memory (HBM).

As shown in FIG. 4A, the 3D memory structure 400 includes the first memory die 420 including first multilayer contact pads (CP1) having a first outer pad (OUTER1) composed of a first conductive material. For example, the first conductive layer is copper (Cu), although other conductive layers are contemplated. The 3D memory structure 400 further includes the base logic die 410 have second multilayer contact pads (CP2) having a second outer pad (OUTER2) composed of the same, first conductive material (e.g., copper (Cu)). In various aspects of the present disclosure, hybrid bonding links (HBL) are coupled between the second outer pad OUTER2 of the second multilayer contact pads CP2 of the base logic die 410 and the first outer pad OUTER1 of the first multilayer contact pads CP1 of the first memory die 420. In this implementation, the hybrid bonding links HBL are composed of the same first conductive material (e.g., Cu).

Various aspects of the present disclosure utilize the hybrid bonding links HBL for enabling DRAM testing and repair using aluminum (Al) pads or a first inner pad (INNER1), or a second inner pad (INNER2), while supporting a lower contact resistance. In some implementations, a multilayer contact pad (e.g., CP1/CP2) utilizes a thin film of titanium nitride (TiN) as a buffer layer (B) to prevent oxidation of the Al test pads (TP), which form an inner pad of the of the multilayer contact pad. In this implementation, a contact resistance is lowered by performing copper (Cu) pad deposition as the outer pad on active Al/TiN pads post repair using the test pad TP, which completes formation of the multilayer contact pads (e.g., CP1, CP2).

In various aspects of the present disclosure, the hybrid bonding links HBL are coupled between the outer pad (e.g., OUTER1/OUTER2 pad) of the multilayer contact pads (e.g., CP1, CP2) to provide a face-to-face bonding of the first memory die 420 and the base logic die 410. Additionally, a backside through silicon via (BTSV) extends from a backside (BS) of the first memory die 420 to a back-end-of-line (BEOL) layer. Although a single memory die is shown, it should be recognized that the 3D memory structure 400 may support a stack of the first memory die 420 on the base logic die 410.

According to various aspects of the present disclosure, the disclosed hybrid bonding links HBL between the multilayer contact pads (e.g., CP1, CP2) improve DRAM yield, while significantly lowering the contact resistance (e.g., by 90%) as well as the power consumption. This lowered contact resistance is a key performance index (KPI) for enabling AI server parts. In this implementation, the multilayer pad structure (e.g., CP1, CP2) protects the Al pads of the inner pad using a thin TiN film as the buffer layer B followed by Cu pad deposition as an outer pad (e.g., OUTER1/OUTER2) to complete the multilayer contact pads (e.g., CP1, CP2). Additionally, the multilayer contact pads (e.g., CP1, CP2) enable both DRAM part repair as well as hybrid bonding with a lower contact resistance. In this implementation, a width of the multilayer contact pads (e.g., CP1, CP2) may be in the range of five (5) microns (μm).

As shown in FIG. 4B, a 3D memory structure 450 is implemented using hybrid bonding links HBL to provide face-to-back (F2B) hybrid bonding of a second memory die 430 and the base logic die 410. The second memory die 430 is similar to the first memory die 420 and is illustrated with similar references characters. As shown in FIG. 4C, a 3D memory structure 470 is implemented using a hybrid bonding links (HBL) to provide face-to-back (F2B) hybrid bonding of the second memory die 430 and a third memory die 440 of, for example, a high-bandwidth memory (HBM). The third memory die 440 is similar to the second memory die 430 and is illustrated with similar references characters. As shown in FIGS. 4B and 4C, the BTSV extends from the backside BS and through a backside semiconductor (silicon (Si)) and lands on the BEOL layer.

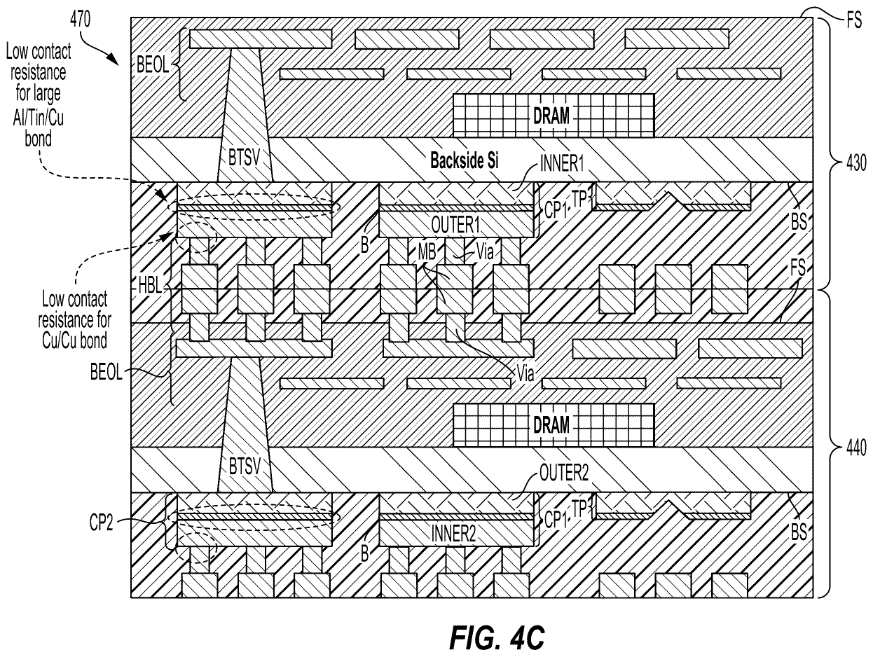

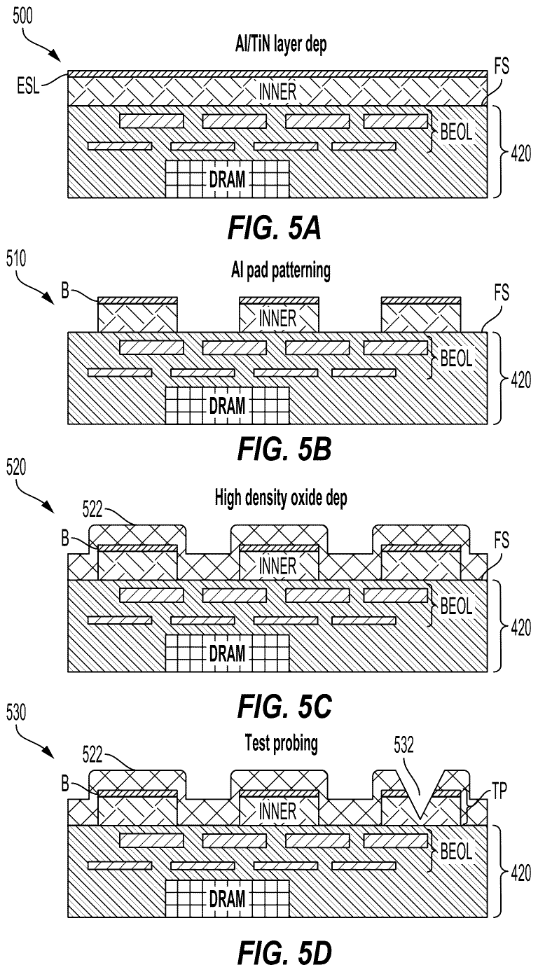

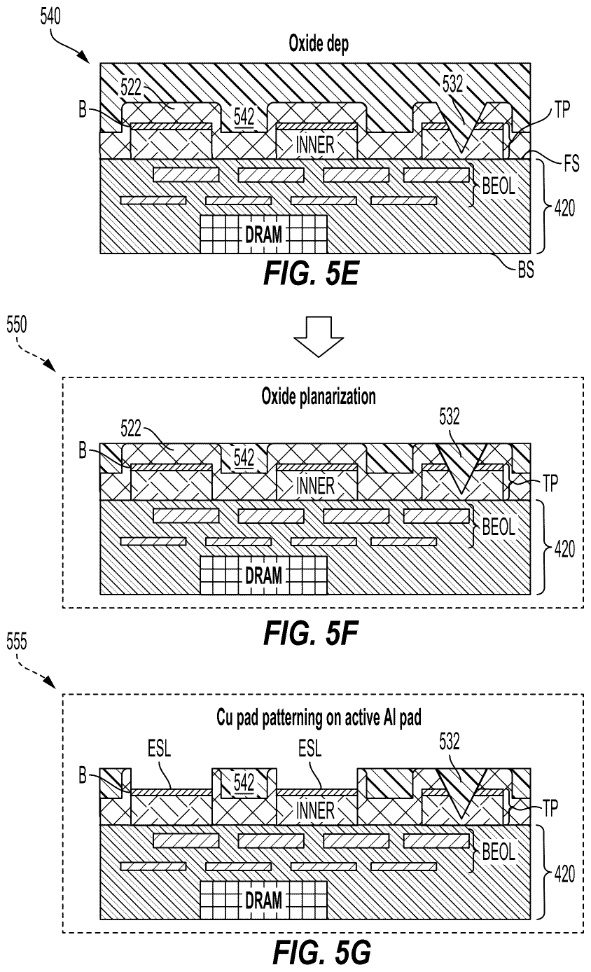

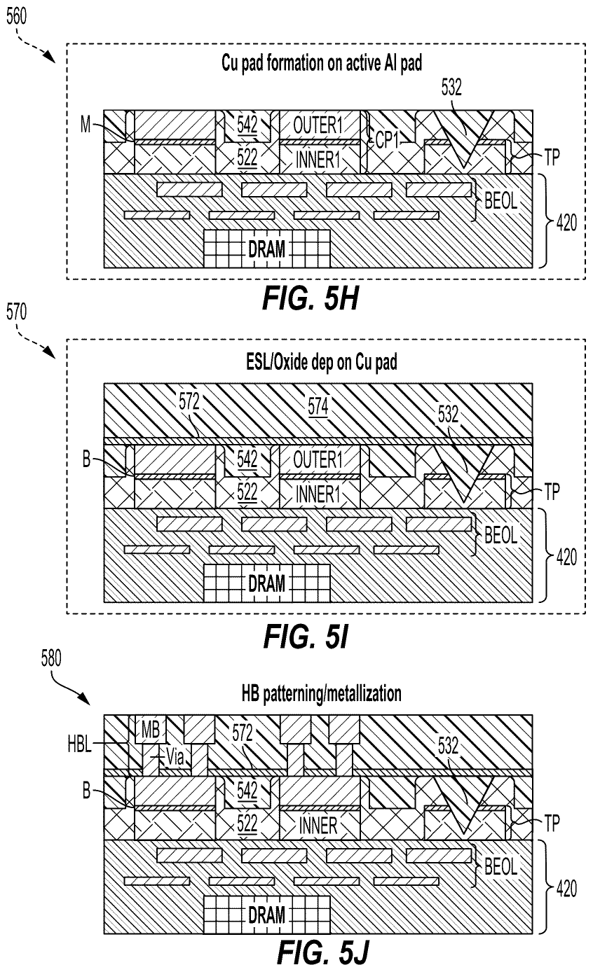

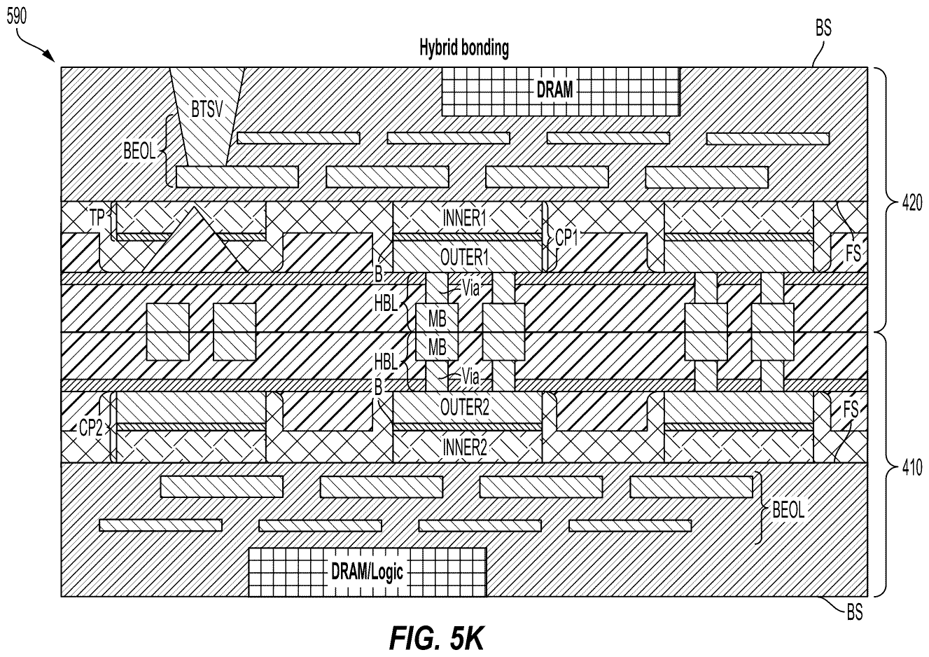

In various aspects of the present disclosure, the 3D memory structure 400 having the hybrid bonding links HBL is integrated in the stacked IC package 200 with hybrid bonding of the first memory die 420 and the base logic die 410 with reduced contact resistance. A process of fabricating the 3D memory structure 400 of FIG. 4A is illustrated, for example, in FIGS. 5A-5K.

FIGS. 5A-5K are cross-sectional diagrams illustrating a process for fabricating the three-dimensional (3D) memory structure 400 of FIG. 4A, having hybrid bonding links for contact resistance reduction, according to various aspects of the present disclosure.

FIG. 5A illustrates a first step 500 for fabricating the 3D memory structure 400, according to various aspects of the present disclosure. At the first step 500, the first memory die 420 is formed, including the BEOL. In this example, a buffer layer and an inner pad (INNER) of a multilayer contact pad (e.g., CP1) are formed by depositing an aluminum (Al) layer on a face (e.g., a frontside (FS)) of the first memory die 420. Additionally, an etch stop layer (ESL) is deposited on the Al layer as the buffer layer B. For example, the ESL may be formed using a titanium nitride (TiN) film, a silicon carbide (SiC) film or other like low resistance film.

FIG. 5B illustrates a second step 510 for fabricating the 3D memory structure 400, according to various aspects of the present disclosure. The second step 510 illustrates patterning of the Al layer and the ESL to expose the frontside FS of the first memory die 420 and form the Al pads as the inner pad of the first multilayer contact pads CP1 including the ESL as the buffer layer B.

FIG. 5C illustrates a third step 520 for fabricating the 3D memory structure 400, according to various aspects of the present disclosure. The third step 520 illustrates deposition of a high-density oxide 522 on the frontside FS of the first memory die 420 and on the INNER layer pads (e.g., Al pads).

FIG. 5D illustrates a fourth step 530 for fabricating the 3D memory structure 400, according to various aspects of the present disclosure. As shown in the fourth step 530, the test pad TP of the first memory die 420 is used to test the first memory die 420, where a test probe can land onto the INNER layer pad. Such probing can damage the INNER layer pad (e.g., Al pad), leaving behind scratches and/or dents on the INNER layer pad, such as a dent 532 shown in FIG. 5D.

FIG. 5E illustrates a fifth step 540 for fabricating the 3D memory structure 400, according to various aspects of the present disclosure. The fifth step 540 illustrates deposition of an oxide 542 on the frontside FS of the first memory die 420.

FIG. 5F illustrates a sixth step 550 for fabricating the 3D memory structure 400, according to various aspects of the present disclosure. The sixth step 550 illustrates planarization of the oxide 542 to expose portions of the high-density oxide 522.

FIG. 5G illustrates a seventh step 555 for fabricating the 3D memory structure 400, according to various aspects of the present disclosure. The seventh step 555 illustrates patterning of an upper portion of the first contact pads CP1 to expose the ESL on the active INNER pads, which excludes the test pad TP.

FIG. 5H illustrates an eighth step 560 for fabricating the 3D memory structure 400, according to various aspects of the present disclosure. The eighth step 560 illustrates formation of the first outer pad (OUTER1 pad) of the first contact pads CP1 on active INNER pads, which excludes the test pad TP. In this example, the OUTER1 pad is formed by depositing a layer of copper (Cu) on the expose ESL on the active INNER pads to form a copper (Cu) pad as the OUTER1 pad as the upper portion of the first contact pads CP1.

FIG. 5I illustrates a ninth step 570 for fabricating the 3D memory structure 400, according to various aspects of the present disclosure. The ninth step 570 illustrates formation of an etch stop layer (ESL) 572 on the OUTER1 pads and the test pad TP. Additionally, a further layer of oxide 574 is deposited on the ESL 572.

FIG. 5J illustrates a tenth step 580 for fabricating the 3D memory structure 400, according to various aspects of the present disclosure. The tenth step 580 illustrates hybrid bond patterning and metallization to formation of hybrid bonding links (HBL) on the OUTER1 pads. In this example, the HBL includes a via landing on the OUTER1 pads and supporting a metal block (e.g., copper (Cu). In this implementation, a width of the metal block (MB) may be in the range of one (1) to seven-tenths (0.7) of a micron (μm) and a width of the vias is in the range of a half (0.5) micron (μm).

FIG. 5K illustrates a final step 590 for fabricating the 3D memory structure 400, according to various aspects of the present disclosure. The final step 590 illustrates completion of the 3D memory structure 400. In this example, the hybrid bonding links HBL on the OUTER1 pads of the first memory die 420 are hybrid bonded to the hybrid bonding links HBL on the OUTER2 pads of the base logic die 410 using a heat treatment process to permanently bond the metal blocks MB of the HBL. In this example, the HBL includes a via landing on the OUTER1 pads and supporting a metal block (e.g., copper (Cu) as well as a via landing on the OUTER2 pads and supporting a metal block MB.

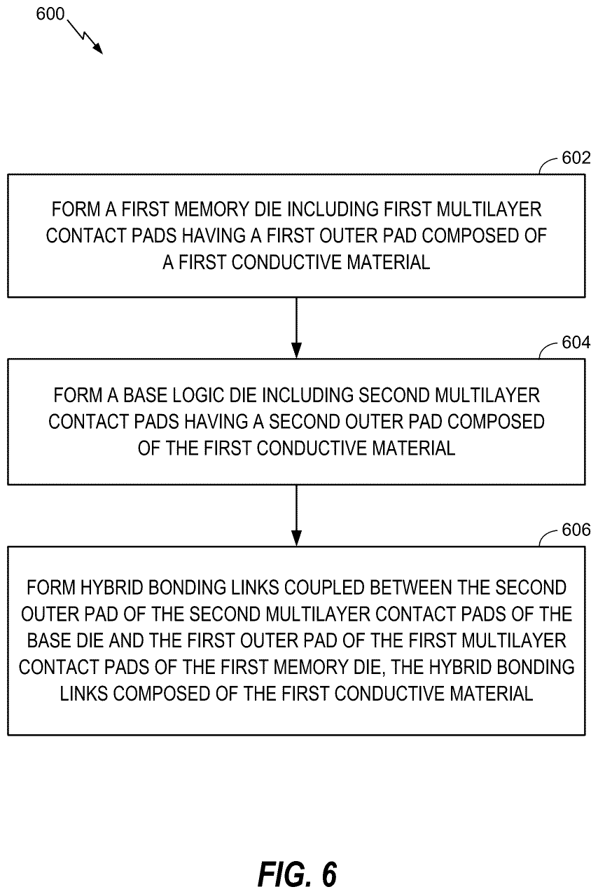

FIG. 6 is a process flow diagram illustrating a method 600 for forming a three-dimensional (3D) memory structure, according to various aspects of the present disclosure. The method 600 begins at block 602, in which a first memory die is formed to include first multilayer contact pads having a first outer pad composed of a first conductive material. At block 604, a base logic die is formed to include second multilayer contact pads having a second outer pad composed of the first conductive material.

At block 606, hybrid bonding links are form between the second outer pad of the second multilayer contact pads of the base logic die and the first outer pad of the first multilayer contact pads of the first memory die. The hybrid bonding links are composed of the first conductive material. For example, as shown in FIG. 5K illustrates the final step 590 for fabricating the 3D memory structure 400, according to various aspects of the present disclosure. The final step 590 illustrates completion of the 3D memory structure 400. In this example, the hybrid bonding links HBL on the OUTER1 pads of the first memory die 420 are hybrid bonded to the hybrid bonding links HBL on the OUTER2 pads of the base logic die 410 using a heat treatment process to permanently bond the metal blocks MB of the HBL. In this example, the HBL includes a via landing on the OUTER1 pads and supporting a metal block (e.g., copper (Cu) as well as a via landing on the OUTER2 pads and supporting a metal block MB.

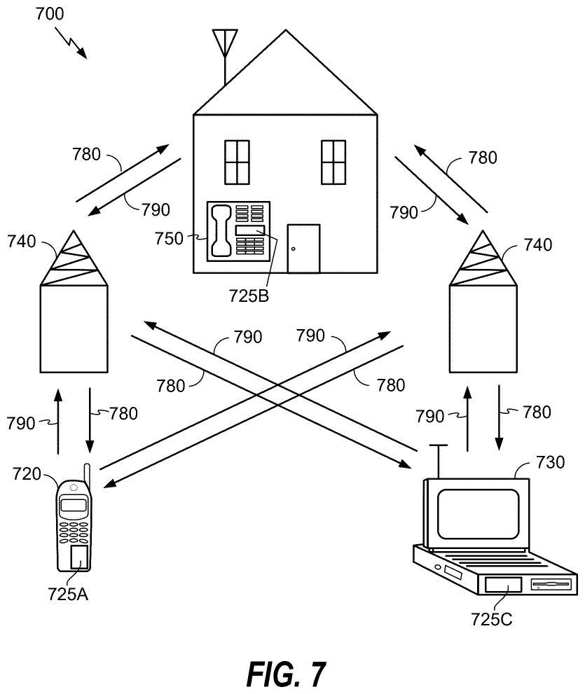

FIG. 7 is a block diagram showing an exemplary system 700, in which an aspect of the present disclosure may be advantageously employed. For purposes of illustration, FIG. 7 shows three remote units 720, 730, and 750, and two base stations 740. It will be recognized that wireless communications systems may have many more remote units and base stations. Remote units 720, 730, and 750 include integrated circuit (IC) devices 725A, 725B, and 725C that include the disclosed 3D memory structure. It will be recognized that other devices may also include the disclosed 3D memory structure, such as the base stations, switching devices, and network equipment. FIG. 7 shows forward link signals 780 from the base stations 740 to the remote units 720, 730, and 750, and reverse link signals 790 from the remote units 720, 730, and 750 to the base stations 740.

In FIG. 7, remote unit 720 is shown as a mobile telephone, remote unit 730 is shown as a portable computer, and remote unit 750 is shown as a fixed location remote unit in a wireless local loop system. For example, the remote units may be a mobile phone, a hand-held personal communication systems (PCS) unit, a portable data unit, such as a personal data assistant, a GPS enabled device, a navigation device, a set top box, a music player, a video player, an entertainment unit, a fixed location data unit, such as meter reading equipment, or other device that stores or retrieves data or computer instructions, or combinations thereof. Although FIG. 7 illustrates remote units according to the aspects of the present disclosure, the disclosure is not limited to these exemplary illustrated units. Aspects of the present disclosure may be suitably employed in many devices, which include the disclosed 3D memory structure.

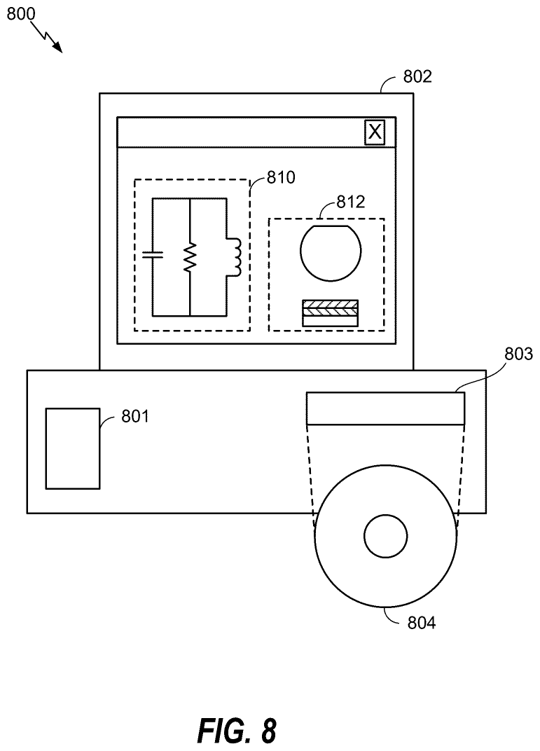

FIG. 8 is a block diagram illustrating a design workstation 800 used for circuit, layout, and logic design of a semiconductor component, such as the 3D stacked chip disclosed above. The design workstation 800 includes a hard disk 801 containing operating system software, support files, and design software such as Cadence or OrCAD. The design workstation 800 also includes a display 802 to facilitate design of a circuit 810 or a semiconductor component 812, such as the 3D stacked chip. A storage medium 804 is provided for tangibly storing the design of the circuit 810 or the semiconductor component 812 (e.g., the 3D memory structure). The design of the circuit 810 or the semiconductor component 812 may be stored on the storage medium 804 in a file format such as GDSII or GERBER. The storage medium 804 may be a CD-ROM, DVD, hard disk, flash memory, or other appropriate device. Furthermore, the design workstation 800 includes a drive apparatus 803 for accepting input from or writing output to the storage medium 804.

Data recorded on the storage medium 804 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 804 facilitates the design of the circuit 810 or the semiconductor component 812 by decreasing the number of processes for designing semiconductor wafers.

### Implementation Examples Are Described in the Following Numbered Clauses:

1. A three-dimensional (3D) memory structure, comprising:
   a first memory die comprising first multilayer contact pads having a first outer pad comprising a first conductive material;
   a base logic die comprising second multilayer contact pads having a second outer pad comprising the first conductive material; and
   hybrid bonding links coupled between the second outer pad of the second multilayer contact pads of the base logic die and the first outer pad of the first multilayer contact pads of the first memory die, the hybrid bonding links comprising the first conductive material.
2. The 3D memory structure of clause 1, in which the first conductive material comprises copper (Cu).
3. The 3D memory structure of any of clauses 1 or 2, in which the first multilayer contact pads comprise:
a first inner pad on a face of the first memory die; and
a buffer layer between the first inner pad and the first outer pad.
4. The 3D memory structure of clause 3, in which the first inner pad comprise aluminum (Al), the buffer layer comprises titanium nitride (TiN), and the first outer pad comprises copper (Cu).

5. The 3D memory structure of any of clauses 1-4, in which the second multilayer contact pads comprise:
a second inner pad on a face of the first memory die; and
a buffer layer between the second inner pad and the second outer pad.
6. The 3D memory structure of clause 5, in which the second inner pad comprise aluminum (Al), the buffer layer comprises titanium nitride (TiN), and the second outer pad comprises copper (Cu).

7. The 3D memory structure of any of clauses 1-6, in which the first multilayer contact pads on a face of the first memory die, and the first outer pad being opposite a backside of the first memory die.

8. The 3D memory structure of any of clauses 1-7, in which the second multilayer contact pads on a face of the base logic die and the second outer pad being opposite a backside of the base logic die.

9. The 3D memory structure of any of clauses 1-8, in which the first memory die comprises a dynamic random-access memory (DRAM) die.

10. The 3D memory structure of any of clauses 1-9, further comprising a test pad on a face of the first memory die.

11. A method for forming a three-dimensional (3D) memory structure, the method comprising:
forming a first memory die comprising first multilayer contact pads having a first outer pad comprising a first conductive material;
forming a base logic die comprising second multilayer contact pads having a second outer pad comprising the first conductive material; and
forming hybrid bonding links coupled between the second outer pad of the second multilayer contact pads of the base logic die and the first outer pad of the first multilayer contact pads of the first memory die, the hybrid bonding links comprising the first conductive material.

For a firmware and/or software implementation, the methodologies may be implemented with modules (e.g., procedures, functions, and so on) that perform the functions described. A machine-readable medium tangibly embodying instructions may be used in implementing the methodologies described. For example, software codes may be stored in a memory and executed by a processor unit. Memory may be implemented within the processor unit or external to the processor unit. As used, the term “memory” refers to types of long term, short term, volatile, nonvolatile, or other memory and is not limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include random-access memory (RAM), read-only memory (ROM), electrically erasable read-only memory (EEPROM), compact disc read-only memory (CD-ROM) or other optical disk storage, magnetic disk storage or other magnetic storage devices, or other medium that can be used to store desired program code in the form of instructions or data structures and that can be accessed by a computer. Disk and disc, as used, include compact disc (CD), laser disc, optical disc, digital versatile disc (DVD), floppy disk, and Blu-ray® disc, where disks usually reproduce data magnetically, while discs reproduce data optically with lasers. Combinations of the above should also be included within the scope of computer-readable media.

In addition to storage on computer-readable medium, instructions and/or data may be provided as signals on transmission media included in a communications apparatus. For example, a communications apparatus may include a transceiver having signals indicative of instructions and data. The instructions and data are configured to cause one or more processors to implement the functions outlined in the claims.

Although the present disclosure and its advantages have been described in detail, various changes, substitutions, and alterations can be made without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above, and below may refer to sides of a substrate or electronic device. Moreover, the scope of the present disclosure is not intended to be limited to the configurations of the process, machine, manufacture, composition of matter, means, methods, and steps described in the specification. As one of ordinary skill in the art will readily appreciate from the present disclosure, processes, machines, manufacture, compositions of matter, means, methods, or steps, presently existing or later to be developed that perform the same function or achieve the same result as the corresponding configurations described may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the present disclosure may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the application and design constraints imposed on the overall system. Skilled artisans may implement the described functionality in varying ways for each application, but such implementation decisions should not be interpreted as causing a departure from the scope of the present disclosure.

The various illustrative logical blocks, modules, and circuits described in connection with the disclosure may be implemented or performed with a general-purpose processor, a digital signal processor (DSP), an application-specific integrated circuit (ASIC), a field-programmable gate array (FPGA) or other programmable logic device, discrete gate or transistor logic, discrete hardware components, or any combination thereof designed to perform the functions described. A general-purpose processor may be a microprocessor, but, in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the present disclosure may be embodied directly in hardware, in a software module executed by a processor, or in a combination of the two. A software module may reside in RAM, flash memory, ROM, erasable programmable read-only memory (EPROM), EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

The previous description of the present disclosure is provided to enable any person skilled in the art to make or use the present disclosure. Various modifications to the disclosure will be readily apparent to those skilled in the art, and the generic principles defined may be applied to other variations without departing from the spirit or scope of the disclosure. Thus, the present disclosure is not intended to be limited to the examples and designs described but is to be accorded the widest scope consistent with the principles and novel features disclosed.

What is claimed is:

1. A three-dimensional (3D) memory structure, comprising:
a first memory die comprising first multilayer contact pads having a first outer pad comprising a first conductive material;
a base logic die comprising second multilayer contact pads having a second outer pad comprising the first conductive material; and
hybrid bonding links coupled between the second outer pad of the second multilayer contact pads of the base logic die and the first outer pad of the first multilayer contact pads of the first memory die, the hybrid bonding links comprising the first conductive material.

2. The 3D memory structure of claim 1, in which the first conductive material comprises copper (Cu).

3. The 3D memory structure of claim 1, in which the first multilayer contact pads comprise:
a first inner pad on a face of the first memory die; and
a buffer layer between the first inner pad and the first outer pad.

4. The 3D memory structure of claim 3, in which the first inner pad comprise aluminum (Al), the buffer layer comprises titanium nitride (TiN), and the first outer pad comprises copper (Cu).

5. The 3D memory structure of claim 1, in which the second multilayer contact pads comprise:
a second inner pad on a face of the first memory die; and
a buffer layer between the second inner pad and the second outer pad.

6. The 3D memory structure of claim 5, in which the second inner pad comprise aluminum (Al), the buffer layer comprises titanium nitride (TiN), and the second outer pad comprises copper (Cu).

7. The 3D memory structure of claim 1, in which the first multilayer contact pads on a face of the first memory die, and the first outer pad being opposite a backside of the first memory die.

8. The 3D memory structure of claim 1, in which the second multilayer contact pads on a face of the base logic die and the second outer pad being opposite a backside of the base logic die.

9. The 3D memory structure of claim 1, in which the first memory die comprises a dynamic random-access memory (DRAM) die.

10. The 3D memory structure of claim 1, further comprising a test pad on a face of the first memory die.

11. A method for forming a three-dimensional (3D) memory structure, the method comprising:
forming a first memory die comprising first multilayer contact pads having a first outer pad comprising a first conductive material;
forming a base logic die comprising second multilayer contact pads having a second outer pad comprising the first conductive material; and
forming hybrid bonding links coupled between the second outer pad of the second multilayer contact pads of the base logic die and the first outer pad of the first multilayer contact pads of the first memory die, the hybrid bonding links comprising the first conductive material.

12. The method of claim 11, in which the first conductive material comprises copper (Cu).

13. The method of claim 11, in which the first multilayer contact pads comprise:
a first inner pad on a face of the first memory die; and
a buffer layer between the first inner pad and the first outer pad.

14. The method of claim 13, in which the first inner pad comprise aluminum (Al), the buffer layer comprises titanium nitride (TiN), and the first outer pad comprises copper (Cu).

15. The method of claim 11, in which the second multilayer contact pads comprise:
a second inner pad on a face of the first memory die; and
a buffer layer between the second inner pad and the second outer pad.

16. The method of claim 15, in which the second inner pad comprise aluminum (Al), the buffer layer comprises titanium nitride (TiN), and the second outer pad comprises copper (Cu).

17. The method of claim 11, in which the first multilayer contact pads on a face of the first memory die, and the first outer pad being opposite a backside of the first memory die.

18. The method of claim 11, in which the second multilayer contact pads on a face of the base logic die and the second outer pad being opposite a backside of the base logic die.

19. The method of claim 11, in which the first memory die comprises a dynamic random-access memory (DRAM) die.

20. The method of claim 11, further comprising a test pad on a face of the first memory die.
